(19) United States
(12) Patent Application Publication
(10) Pub. No.: US 2011/0154269 A1
(43) Pub. Date: Jun. 23, 2011

(54) HOME ENERGY MANAGEMENT SCREENSAVER

(75) Inventors: Jay Andrew Broniak, Louisville, KY (US); Natarajan Venkatakrishnan, Louisville, KY (US); Joseph Mark Brian, Louisville, KY (US); Byron K. Guernsey, Charlestown, IN (US); David C. Bingham, Louisville, KY (US)

(73) Assignee: General Electric Company

(21) Appl. No.: 12/644,458

(22) Filed: Dec. 22, 2009

(51) Int. Cl. G06F 3/048; G01R 21/00; G06F 19/00

(52) U.S. Cl. 715/867; 702/62

(57) ABSTRACT

A computer screensaver program runs a home energy manager application. The screensaver program is activated after a predetermined time and automatically runs a web browser by detecting the URL of the home energy manager application. The home energy manager interface is then displayed on the computer screen or a remote monitor. Preferably, the screensaver cycles through one or more various screens and remains active until a key is pressed or the mouse is activated.

### BACKGROUND OF THE DISCLOSURE

The present disclosure relates to a system that provides a homeowner with the ability to monitor and manage energy consumption, sometimes referred to as a home energy manager system. More particularly, this disclosure relates to providing consumers with the ability to quickly monitor or view their home energy consumption without having to specifically log into a computer and launch a home energy manager application.

Systems have been recently developed in which one or more appliances communicate with a home energy manager to receive a demand supply management signal and/or data and provide the homeowner with the opportunity for a possible load shedding event in the appliance in response thereto. The home energy manager provides the homeowner the means to monitor and manage the energy consumption and associated cost. Either behavior modification or programmed control logic can be used to monitor and manage the energy consumption. Typically, a central device (utility meter, neighborhood central processor, demand supply management module, etc.) provides real time data on electricity, water, natural gas, or other utility consumption or solar photovoltaic generation. A user interface allows the homeowner to accept a recommended course of action which may result in alteration of the operation of one or more home appliances, or the homeowner may be able to preprogram desired operations to be undertaken in response to the demand supply management signal/data.

One manner of monitoring the consumption is to display the information on a monitor or screen. Alternatively, the personal computer (PC) of the homeowner is networked with the home energy manager system and the energy usage or energy cost data is displayed on the networked PC through a web browser. In this latter instance, when the homeowner uses the PC and displays the information through a web browser, the homeowner is required to physically run the web browser in order to access the data. In many instances this is sufficient to keep the homeowner apprised of the energy consumption and associated energy costs. On the other hand, this does not necessarily permit the homeowner to quickly and easily view the energy consumption/costs since this arrangement requires the homeowner to run the home energy manager application while using the home computer.

Instead, a quick view on an instantaneous basis that allows a homeowner at a glance to quickly assess the energy consumption/cost, for example, as the homeowner performs various other tasks around the home would be desirable. Moreover, the ability to view energy consumption/cost information without being logged into a personal computer would also be desirable. Because the home computer is used for running many other programs, the homeowner will likely need to log back into the computer or log back onto the home energy manager software in order to view the utility consumption/cost data. Thus, although many household computers are continually left running, and the home PC is often located in a high traffic area, it becomes necessary to either provide a stand alone, “always on” device that displays energy consumption/cost (for example a small LCD screen on the appliance that displays energy consumption) or to use the computer to display the information but only when the computer is running the home energy manager system and only when the monitor is active.

Accordingly, a need exists for an inexpensive, clever manner of keeping the homeowner up-to-date regarding such utility or energy consumption and associated cost.

### SUMMARY OF THE DISCLOSURE

A screensaver program for communicating information relating to homeowner energy consumption includes a set point for activating the screensaver program after a predetermined time period of inactivity. Instructions are provided for running a web browser relating to home appliance energy consumption through the screen saver program.

The URL of the web browser is automatically detected during installation of the screensaver program. The screensaver program is loaded on a computer or accessed via the computer such that the controller or CPU operatively communicates with the monitor or screen, for displaying a screensaver that includes home energy usage and/or cost information that is updated with this information.

The controller is instructed by the screensaver program to automatically detect the URL of the home energy manager system once a predetermined period of time of inactivity has elapsed that triggers or activates the screensaver.

A remote second monitor, such as a mobile phone, may also receive and display the screensaver information.

Displaying utility usage data or cost on at least a portion of the monitor or a remote device in response to activation of the screensaver is one manner of displaying information relating to home energy consumption or cost.

The displaying step may further include displaying utility usage data on the monitor during non-screensaver activity.

The displaying step includes progressively cycling the display through various screens.

The operating step includes running a web browser within a monitor screensaver.

A primary benefit is to provide greater value and appeal for a homeowner without the cost of a separate display and without requiring the homeowner to be constantly accessing the home energy manager application via a web browser on the home PC.

Another benefit is the ability to display energy consumption/cost data at all times, therefore making the system more useful and meaningful to the homeowner.

While some systems have a stand alone, “always on” device that constantly displays energy consumption and other homeowners use a personal computer to display the information while actively operating or running the browser, the “always on” device is expensive and the information is not accessible during a screensaver operation.

Still other benefits and advantages of the present disclosure will become apparent upon reading and understanding the following detailed description.

### BRIEF DESCRIPTION OF THE DRAWINGS

FIG. 1 is schematic illustration of a home energy management system.

FIG. 2 is a schematic representation of a home energy manager network system, along with a second monitor.

FIG. 3 is a screen shot of the subject screensaver.

FIG. 4 is a screen shot of the screensaver.

FIG. 5 is yet another screen shot of the preferred screensaver.

### DETAILED DESCRIPTION OF THE PREFERRED EMBODIMENTS

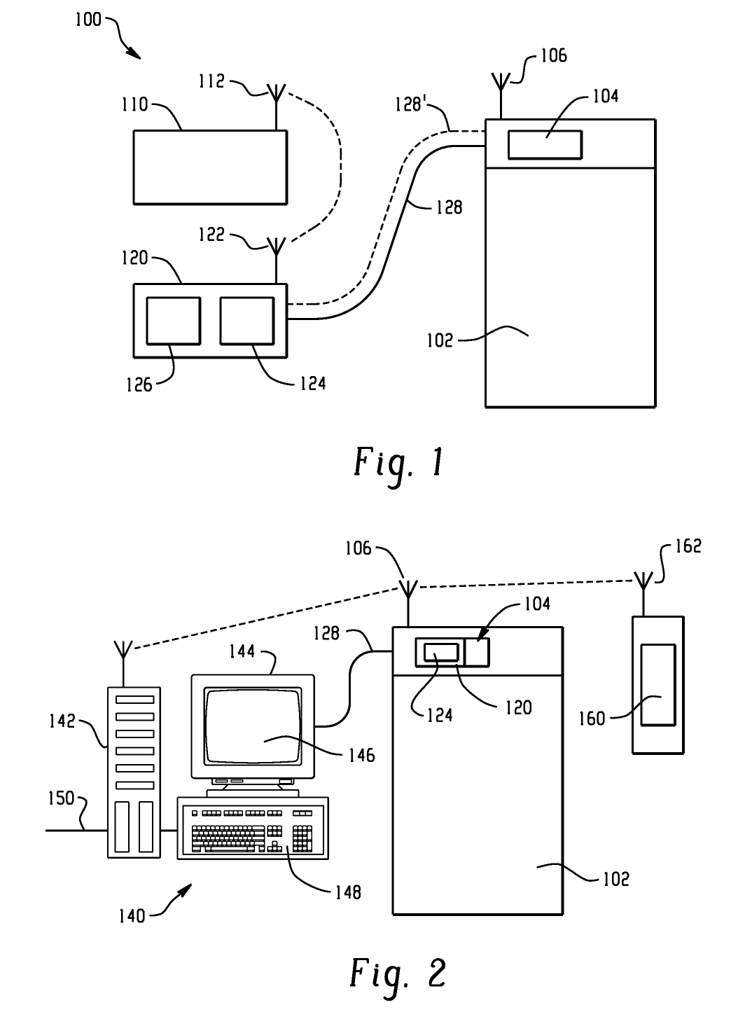

Turning first to FIG. 1, a first embodiment of a demand/response or demand/supply management system 100 is schematically illustrated. The system 100 includes one or more home appliances 102. Each appliance 102 includes a controller, such as a microprocessor or microcontroller 104, that monitors and controls operational aspects of the home appliance. An antenna 106 is associated with the appliance to receive a wireless signal, and is operatively connected to the home appliance controller. Typically, the antenna is in communication with a transmitter 110 such as associated with a utility (electricity, gas, water, etc.) which may have an antenna 112 for emitting a signal or data, particularly relating to energy usage or demand, and/or the cost associated therewith. Although in some instances, and to be described with reference to FIG. 2, the signal/data may be directly received by the individual home appliance, typically the system includes a home energy manager module 120 that has an antenna 122 adapted to receive the signal/data from the emitter antenna 112.

Controller 124 associated with the module 120 interprets or translates the energy demand supply signal emitted directly or indirectly from the utility, and the controller 124 provides a representative output through wired connection 128 or wireless connection 128′ with the home appliance. A user interface 126 may also be operatively associated with the module controller. The user interface 126 allows the homeowner to input or program the controller 124 and thereby potentially control operation of one or more home appliances in response to utility demand or utility cost. By way of example only, if the demand for electricity is “high”, then the homeowner is alerted to this fact by a signal that emanates from the transmitter 110 and is conveyed to the module. The controller interprets the signal and the homeowner may be prompted to select a cost savings operation of one or more home appliances, or if the homeowner has programmed a desired operation into the controller 124, the connection 128, 128′ with the home appliance will convey a signal/data to the home appliance controller to undertake a desired operation. For example, operation of the home appliance may be delayed or altered in an effort to save electricity and reduce the cost to operate one or more home appliances.

In some instances, rather than a separate module that communicates with the home appliance, the functional aspects of the module 120 may be incorporated directly into the home appliance as shown in FIG. 2. Here, a controller 104 for operating the home appliance may be integrated with controller 124 of the home energy manager module. Again, a signal/data may be received wirelessly through antenna 106 of the home appliance, or through a wire connection 128 as illustrated schematically in the figure. The home appliance establishes one-way or two-way communication with a personal computer (PC) 140 that includes, for example, a processor 142, a display or monitor 144 having screen 146, and an input device 148 such as a keyboard, mouse, etc. One skilled in the art will also appreciate that signal/data can be received and transmitted from the home computer wirelessly for communication with the home appliance through the antenna 106.

As is common, the computer processor 142 has one or more programs loaded thereon. Typically with today's personal computers, the processor 142 communicates outside of a home network via line 150, such as Ethernet, high speed data line, wireless, etc. In this manner, information and data external to the home network can be transmitted to and received from an external source. Part of the functionality of the home energy manager application is to interact with a web browser to manage the communication with the utility, a neighborhood or subdivision transmitter, or transceiver, etc. that provides information regarding the energy rate or energy level mode and to display this and other information on the monitor screen 146. By way of example only, four relative states of usage such as “low”, “medium”, “high”, and “critical” may be output from the utility and received into the networked processor 142 or conveyed to the controller 124 of the home appliance(s). The application may display on screen 146 for example, real-time data on electricity, water, natural gas, or other utility consumption. It may also display other utility information such as solar or photovoltaic generation, and likewise display other information such as historic utility demand, usage, cost, etc. The particular level of sophistication and complexity of the displayed information may vary, however, information is intended for display to inform the homeowner of utility demand or usage and the costs associated with such use.

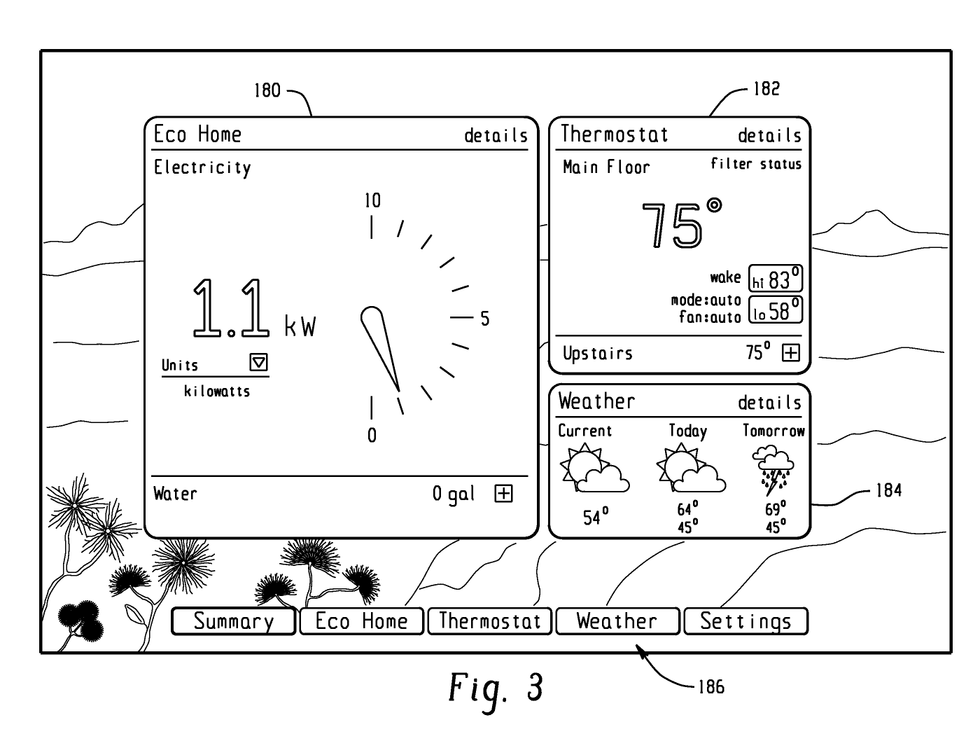

With continued reference to FIG. 2 and additional reference to FIGS. 3-5, the present disclosure does not impact the ability of the homeowner to continue to run or operate the home energy manager application software and, moreover, to illustrate the information either on the PC monitor 146, and/or on a second or remote monitor 160, such as a mobile phone screen, or the like. The mobile phone has a suitable antenna 162 for receiving such data from the home PC and is yet another way in which the homeowner can quickly be apprised of the energy rate or usage in the home.

In addition, however, to typical operation of the home energy manager application, the present disclosure provides a computer screensaver program that displays the content of the home energy manager application that is running all of the time. As is typical with a screensaver program, a predetermined time period or timeout is set by the user so that if no activity is detected by the PC device(s) 148, a screensaver program is activated. In this disclosure, the computer screensaver physically runs a web browser by automatically detecting the URL of the home energy manager application once the timeout period has been reached. The web browser control is activated as a screensaver and the home energy manager interface is displayed on the monitor as an active screensaver.

FIG. 3 illustrates an exemplary screen shot of the home energy manager screensaver. Here, the screensaver is intended to actively display certain information (e.g., eco home details such as electricity usage, water usage, etc. in graphical, iconic, or numeric form, and thermostat operative details, and/or local weather conditions or forecast information). Of course, still other displays or level of detail may be alternately used without departing from the scope and intent of the present disclosure. Because the screensaver is actively displaying the data and updating real time information, it is anticipated that the displayed information will not be static but is a generally dynamic interface that is periodically or intermittently updated to provide the homeowner with substantially instantaneous home energy manager information.

It is also contemplated that although the screensaver could be a single screen such as shown in FIG. 3, another embodiment progressively cycles through a series of screens or displays as shown successively in FIGS. 3, 4, and 5. A general overview of all information is provided in FIG. 3. That is, the left-hand window 180 shows utility or energy usage. In this instance, electricity usage of 1.1 kilowatts is illustrated numerically as well as graphically. Water usage is also demonstrated by way of a graph at the bottom of the window 180. Of course, other information, formats, graphs, etc. could be used with equal success.

A second window 182 provides thermostat information. For example, the temperature of the main floor may be displayed, as well as the programmable information such as is typical in a programmable thermostat. A different location in the home may also be monitored and displayed in the same window 182 as represented by “Upstairs”. Still other information such as the status of the filter, program settings such as fan, air conditioning, auto, etc. may likewise be illustrated.

In yet another or third window 184, additional information may be displayed on the screen of the screensaver program. Again, and by way of example only, the current forecast and weather conditions may be shown. Of course, the screen with multiple windows shown in FIG. 3 is but one example of the information and data that may be provided on the screen. Further, the relative size of the windows may change or can be revised as desired by the homeowner, or the window sizes could sequentially change. A greater or lesser number of windows may be part of the screensaver program, and likewise, the additional windows may also selectively be displayed or cycle as desired.

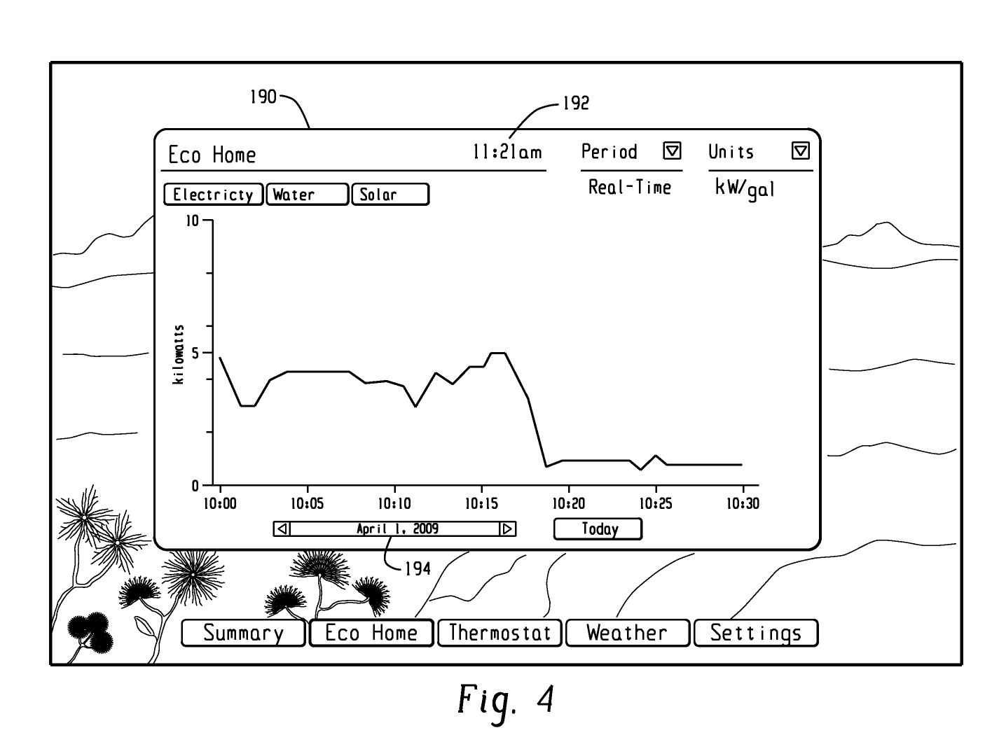

FIG. 4 illustrates an enlarged window 190 on the background that provides not only real-time data home energy management information but also historical data for viewing by the homeowner. Rather than the summary screen of FIG. 3, or in addition to the summary screen of FIG. 3, extra detail is provided in this screen, and particularly in window 190. In this particular graphical representation, electricity usage in the home is illustrated by the number of kilowatts along the y-axis and over time as represented along the x-axis. Similar graphs, charts, representations, color-coding, etc. can be illustrated for other utilities such as water, gas, etc., as well as providing the present time at 192 or present date as illustrated at 194.

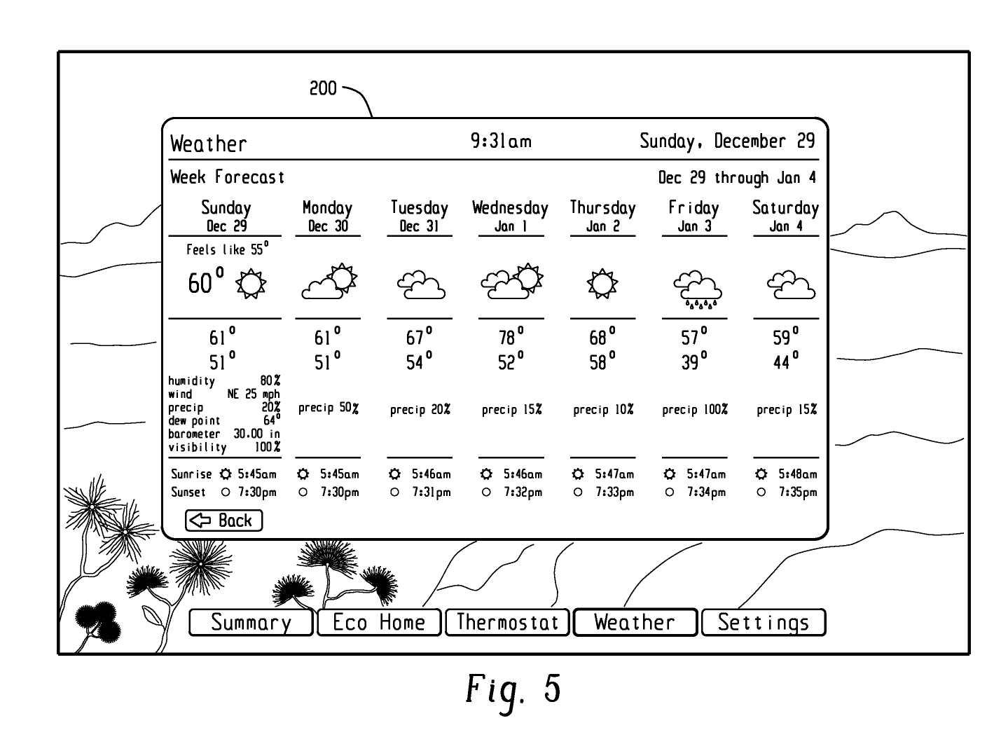

In FIG. 5, still another screen through a cycle is illustrated. Here, the present weather conditions are provided along with the date and time. In addition, a weekly forecast of highs and lows, and anticipated weather conditions for particular dates can be suitably illustrated along with other information such as sunrise and sunset information. Again, such information is merely representative of the type of information that can be shown and should not be deemed limiting since other windows 200 and/or screens could be similarly used.

In the preferred arrangement, the menu 186 shown along the bottom portion of the screen includes a “summary”, “eco home”, “thermostat”, “weather”, and “settings” menu bars. These selections may be cycled through a series of displays, for example automatically and periodically displayed through operation of the screensaver program. In this manner, a wide array of home energy manager data is readily presented to the homeowner.

In summary, once the screensaver is activated, the program preferably cycles through various screens of the home energy manager application. The home energy manager application is running all of the time and is not dependent on any web browser to launch the application. The home energy manager has a web browser as an integral feature. The screensaver launches a web browser and then communicates with the home energy manager web server through that browser to display specific content on the monitor or screen. The homeowner is provided the ability to quickly monitor their home energy consumption without having to log into the computer. Real time feedback on various utilities such as electricity, water, natural gas consumption can all be illustrated. Preferably, the data is displayed on the device's display screen, but can also be conveyed to a remote screen or monitor 160 such as illustrated by the mobile device in FIG. 2.

The computer screensaver program displays the information from the home energy manager application that is running and monitoring energy/utility usage, energy/utility costs, storing historical data, etc. The screensaver program physically runs a web browser, i.e., the home energy manager application, within the context of a computer screensaver. The screensaver program is preferably installed on the computer and during the installation process the program automatically detects the URL of the home energy manager application. Upon the screensaver timeout, which is preferably set by the user, the web browser is activated as a screensaver. The home energy manager interface is displayed on the computer screen or remote device and cycles through one or more of various screen shots, e.g., FIGS. 3-5. The screensaver preferably remains active until a key is pressed or until a mouse is activated. The homeowner has the ability to view energy consumption information without being logged into the personal computer. The homeowner can view the consumption at a glance while walking by the household PC which is typically located in a high traffic area and without requiring the home owner to log into the computer. The screensaver can also be integrated within desktop background to display energy consumption so that such information is always available to the homeowner. The desktop background would have to be modified to be updated and therefore active.

With regard to the mobile device, the same energy consumption information can be displayed on a device other than the home computer monitor or mobile phone, such as a television, home security system screen, thermostat, or other mobile device.

The disclosure has been described with respect to preferred embodiments. Obviously, modifications and alterations may be contemplated by one skilled in the art, and the subject disclosure should not be limited to the particular examples described above but instead through the following claims.

What is claimed is:

1. A screensaver program for communicating information relating to homeowner energy consumption comprising:
a set point for activating the screensaver program after a predetermined time period of inactivity; and
instructions for running a web browser relating to home appliance energy consumption through the screensaver program.

2. The program of claim 1 wherein the URL of the web browser is automatically detected during installation of the program.

3. The program of claim 1 wherein the program displays the web browser.

4. A computer system comprising:
a controller;
a monitor operatively communicating with the controller; and
instructions provided to the controller for displaying a screensaver on the monitor that includes home energy usage information.

5. The computer system of claim 4 wherein the instructions include automatically detecting a URL of a home energy manager system.

6. The computer system of claim 5 wherein the home energy usage information is displayed as a part of the screensaver without running the home energy manager system.

7. The computer system of claim 5 wherein the instructions retrieve the home energy usage information from a networked home energy manager system.

8. The computer system of claim 5 further comprising a remote second monitor for receiving and displaying the screensaver.

9. The computer system of claim 5 further comprising a remote mobile device displaying the screensaver.

10. A method of displaying information relating to homeowner energy consumption on a computing device having a monitor comprising:
running a screensaver on the monitor; and
displaying utility usage data on at least a portion of the monitor in response to activation of the screensaver.

11. The method of claim 10 wherein the utility usage data displaying step includes further displaying the utility usage data on the monitor during non-screensaver activity.

12. The method of claim 10 further comprising connecting with a networked device [home energy manager] in response to activating the screensaver.

13. The method of claim 12 wherein the connecting step includes accessing the networked device through the network.

14. The method of claim 12 wherein the connecting step includes accessing the networked device from a location external to the network.

15. The method of claim 12 wherein the displaying step includes displaying information from the networked device on the monitor.

16. The method of claim 12 wherein the displaying step includes additionally displaying the utility usage data on a remote, second monitor.

17. The method of claim 12 wherein the displaying step includes additionally displaying the utility usage data on a remote mobile device.

18. The method of claim 12 wherein the displaying step includes progressively cycling the display through various screens.

19. The method of claim 12 wherein the running step includes operating a web browser within a monitor screensaver.
